(19) United States
(12) Patent Application Publication
(10) Pub. No.: US 2023/0021102 A1
(43) Pub. Date: Jan. 19, 2023

(54) FLOW RATE CONTROL DEVICE, AND FLOW RATE CONTROL METHOD

(71) Applicant: FUJIKIN INCORPORATED, Osaka (JP)

(72) Inventors: Katsuyuki SUGITA, Osaka-shi (JP); Ryousuke DOHI, Osaka-shi (JP); Koji KAWADA, Osaka-shi (JP); Kouji NISHINO, Osaka-shi (JP); Nobukazu IKEDA, Osaka-shi (JP)

(73) Assignee: FUJIKIN INCORPORATED, Osaka (JP)

(21) Appl. No.: 17/784,011

(22) PCT Filed: Dec. 3, 2020
(86) PCT No.: PCT/JP2020/045117

§ 371 Date: Jun. 9, 2022

(30) Foreign Application Priority Data
Dec. 27, 2019 (JP) 2019-238052

(51) Int. Cl. G05D 7/06; F16K 31/00; C23C 16/52

(52) U.S. Cl. CPC G05D 7/0647; F16K 31/004; C23C 16/52

(57) ABSTRACT

A flow rate control device 100 includes a flow rate control valve 8 having a valve element 8a and a piezoelectric element 8b for moving the valve element, and a control circuit 9 for controlling an operation of the flow rate control valve 8, wherein, in order to perform a pulsed fluid supply, the control circuit 9 is configured so as to open-loop control an applied voltage to the piezoelectric element so that it approaches the target voltage after once applying a voltage V1 exceeding a target voltage V0 corresponding to a target displacement of the piezoelectric element, when a pulsed flow rate setting signal is given.

### TECHNICAL FIELD

The present invention relates to a flow rate control device and a flow rate control method, and more particularly, to a flow rate control device and a flow rate control method used in semiconductor manufacturing equipment, a chemical plant, or the like.

### BACKGROUND ART

In semiconductor manufacturing equipment and chemical plants, various types of flow meters and flow rate control devices are used for controlling the flow rate of material gases or etching gases. Among these, a pressure type flow rate control device is widely used, because it is capable of controlling mass flow rates of various fluids with high accuracy by a relatively simple mechanism that is combined with a control valve and a restriction part (e.g., an orifice plate or a critical nozzle).

Among the pressure type flow rate control devices, there is a kind to control the flow rate of a fluid flowing downstream of the restriction part by controlling a fluid pressure upstream of the restriction part (hereinafter, sometimes referred to as the upstream pressure P1) (for example, Patent Documents 1 and 2). The upstream pressure P1 is controlled by feedback controlling a control valve disposed upstream of the restriction part using a pressure sensor.

As the control valve of the pressure type flow rate control device, a piezoelectric element driven valve configured to open and close a diaphragm valve element by a piezo actuator (hereinafter, sometimes referred to as a piezo valve) is used. The piezo valve, which is disclosed in detail in Patent Document 3 for example, can operate at a relatively high speed.

### PRIOR-ART DOCUMENT

### Patent Documents

Patent literature 1: Japanese Laid-Open Patent Publication No. H8-338546

Patent literature 2: International Patent Publication No. WO2005/003694

Patent literature 3: Japanese Laid-Open Patent Publication No. 2007-192269

Patent literature 4: Japanese Laid-Open Patent Publication No. 2005-293570

Patent literature 5: International Patent Publication No. WO2018/123852

Patent literature 6: International Patent Publication No. WO2019/107215

### SUMMARY OF INVENTION

### Technical Problem

Although the piezo valve is configured by using a piezoelectric element, it is known that a creep phenomenon occurs when driving the piezoelectric element (for example, Patent Document 4). The creep phenomenon is a phenomenon in which displacement continues to increase or decrease slightly with time due to a reorientation of dipoles of the piezoelectric element, even when the driving voltage applied to the piezoelectric element is maintained at constant.

In the flow rate control device having a piezo valve, the occurrence of the creep phenomenon would result in a decrease in the flow rate responsivity due to the delay of the transition to a set valve opening degree, or occurrence of leakage due to the delay until completely closed. In order to prevent the occurrence of leakage, it is also conceivable to take measures such as increasing the urging force of an elastic member to increase the pressing force of the valve element toward the valve seat. However, in this case, there is a risk that the maximum lift amount of the valve is lowered, the controllable flow rate range is narrowed, or the valve seat or the valve element is damaged when repeatedly opening and closing over a long period of time due to the large load applied by the strong pressing force.

The creep phenomenon can be easily corrected by providing a displacement sensor that measures the displacement of the piezoelectric element and feedback controlling the driving voltage based on an output of the displacement sensor. In Patent Documents 5 and 6, the applicant of the present application discloses a flow rate control device configured to measure the displacement of the piezoelectric actuator by using a strain gauge fixed to a piezoelectric element as the displacement sensor.

By using a strain gauge to directly measure the displacement of the piezoelectric element, as compared with the case of referring to the driving voltage, the valve opening degree can be more accurately known, and the valve opening degree can be more precisely adjusted. Thus, it is possible to suppress the creep phenomenon by continuously adjusting the driving voltage and maintaining the valve opening degree at a constant opening degree.

In addition, the piezo valve provided with a displacement sensor has high responsivity as described in Patent Document 5, it can be used as a high-speed servo type control valve. Moreover, as described in Patent Document 6, the flow rate control device may also be configured by providing another piezo valve for pressure control disposed upstream of the piezo valve having a displacement sensor for flow rate control. In this configuration, as well as controlling the upstream pressure using the pressure control valve, by feedback controlling the flow rate control valve based on the output of the displacement sensor, it is possible to perform a highly responsive flow rate control over a wide flow rate range.

As compared with the control valve of the conventional pressure type flow rate control device that is feedback-controlled based on the output of the pressure sensor, the piezo valve having a displacement sensor can accurately grasp the opening and closing state and has much higher responsivity. Thus, in an application where high-speed (in a very short period) pulse control signal is applied, such as in an ALD (Atomic Layer Deposition) process or an ALE (Atomic Layer Etching) process, it is suitably used to pulse supply gas at a desired flow rate.

However, in the recent flow rate control device in which a large flow rate is required, even in the ALD process or the like, the required movement amount of the valve element or the displacement amount of the piezoelectric element increases. In this case, the strain gauge fixed to the piezoelectric element may not be able to accurately measure the displacement. In addition, if a displacement sensor is to be incorporated into the piezo valve for measuring the displacement amount, it may cause problems of increase in the size of the device and increase in cost.

The present invention has been made in view of the above problems, and its main object is to provide a flow rate control device and a flow rate control method capable of appropriately performing high-speed pulsed gas supply at the desired flow rate without providing a displacement sensor to a piezoelectric element.

### Solution to Problem

The flow rate control device according to an embodiment of the present invention includes a flow rate control valve having a valve element and a piezoelectric element for moving the valve element, and a control circuit for controlling the operation of the flow rate control valve, wherein in order to perform a pulsed fluid supply, the control circuit is configured to open-loop control a voltage applied to the piezoelectric element so that a voltage exceeding a target voltage corresponding to a target displacement of the piezoelectric element is once applied and then a voltage approaching the target voltage is applied, when a pulsed flow rate setting signal is given.

In one embodiment, the control circuit is configured to change a control function of the voltage applied to the piezoelectric element depending on the target flow rate indicated by the flow rate setting signal.

In one embodiment, the pulsed flow rate setting signal is a continuous periodic signal having a frequency of 1 Hz or more and 100 Hz or less.

In one embodiment, the flow rate control device further includes a pressure control valve provided upstream of the flow rate control valve, a pressure sensor for measuring a pressure downstream of the pressor control valve and upstream of the flow rate control valve, and a restriction part with a fixed opening degree. The flow rate control device is configured so that, when performing control of a continuous flow, a flow rate control is performed by using the restriction part with a fixed opening degree and based on an output of the pressure sensor, and when performing control of a pulsed flow, a flow rate is performed by using the flow rate control valve as a restriction part with a variable opening degree.

The flow rate control method according to an embodiment of the present invention is performed in a flow rate control device comprising a flow rate control valve having a valve element and a piezoelectric element for moving the valve element. The flow rate control method includes a step of receiving a pulsed flow rate setting signal for performing a pulsed fluid supply, a step of generating an internal command signal for determining a voltage applied to the piezoelectric element based on the flow rate setting signal when receiving the pulsed flow rate setting signal, and a step of applying a voltage to the piezoelectric element based on the generated internal command signal, wherein the internal command signal is generated as a signal approaching a target voltage after once applying a voltage exceeding the target voltage corresponding to a target displacement of the piezoelectric element, and the voltage applied to the piezoelectric element is open-loop controlled.

### Effect of Invention

According to an embodiment of the present invention, a flow rate control device and a flow rate control method capable of appropriately performing pulsed flow rate control are provided.

### BRIEF DESCRIPTION OF DRAWINGS

FIG. 1 is a graph showing a flow rate setting signal and an actual piezo displacement in a pulsed flow rate control.

FIG. 2 illustrates an exemplary flow rate control device according to an embodiment of the present invention.

FIG. 3(a) shows an output of the piezo displacement when using a setting signal without correction, and FIG. 3(b) shows an output of the piezo displacement when using a corrected setting signal.

FIG. 4 is a graph showing an external input signal, and an internal command signal generated on the basis of the external input signal for suppressing the creep phenomenon.

FIG. 5 is a graph showing a setting signal, a piezo driven voltage applied to a piezoelectric element, and valve displacement, FIG. 5(a) shows a case where the valve is driven without generating a corrected internal command signal, FIG. 5(b) shows a case where the valve is driven using a corrected internal command signal.

### DESCRIPTION OF EMBODIMENTS

First, an overview of the flow rate control device according to an embodiment of the present invention will be described. As described above, a piezo valve configured to adjust the opening degree based on the output of the displacement sensor is known, and such a piezo valve is suitably used for pulsed flow rate control because of its very high responsivity. However, in order to fulfill large flow rate applications, it will be advantageous if pulsed flow rate control can be performed by a piezo valve without using a displacement sensor.

When not using a displacement sensor, since it is impossible to adjust the opening degree by the feedback control, it is assumed that the control of the valve opening degree is performed in the open-loop control (feedforward control) based on the setting signal. Then, in this case, since there is no means for measuring the actual piezo displacement, it is considered difficult to suppress the creep phenomenon. Therefore, the inventors of the present application have intensively examined whether or not a significant creep phenomenon occurs and adversely affects the flow rate control even when the pulsed flow rate control is performed by a continuous cycle signal of, for example, about 10 Hz.

In addition, rather than the pulsed flow rate control, when performing the flow rate control of a continuous flow, as in the conventional pressure type flow rate control device, it is sufficient to perform the feedback control of the control valve based on the measurement result of the upstream pressure P1 upstream of the restriction part. When the flow rate control is performed by controlling the upstream pressure P1 by adjusting the opening degree of the control valve, it is not necessary to measure the actual valve opening degree using the displacement sensor, and it is not necessary to consider the creep phenomenon.

FIG. 1 is a graph showing the valve displacement SV when the pulsed flow rate setting signal SF is given at 12.5 Hz, which is obtained by the experiments of the present inventors. The piezoelectric driving voltage alternately repeats between 0 V and 140 V. As can be seen from FIG. 1, even when a high-frequency drive of 12.5 Hz is performed, due to the creep phenomenon, the actual valve displacement continues to increase slowly once after a sudden rise at the time of rising and then decreases slowly after a sudden fall at the time of falling. In particular, the opening degree drops to only 2 to 3% immediately after the fall, and then gradually approaches 0%, and a leak occurrence may be confirmed.

When such a creep phenomenon occurs, in particular in the pulse flow rate control required by the ALD process, the flow rate control may be inadequate. This is because, in the ALD process, not only the gas flow rate but also the volume of the gas to be supplied (integral flow rate) are important, in the gas supply while the creep phenomenon remains, errors in both the gas flow rate and the gas volume are increased to cause a failure in the process.

Based on the above discussion, the inventors of the present application have recognized that it is extremely important to suppress the creep phenomenon of the piezo valve even when performing the flow rate control based on the pulsed setting signal of a high frequency. Then, it was found that, even without using the feedback control which has been considered necessary for the flow rate control device of high accuracy, if the voltage applied to the piezoelectric element is appropriately controlled, the pulsed flow rate control may be appropriately performed while the creep phenomenon is suppressed. In addition, it was found that the characteristic of the creep phenomenon itself does not change so much even when performing a large number of opening and closing operations, therefore, even though driven by the open-loop control, the creep phenomenon may be suppressed over a long period, and the pulsed flow rate control may also be performed appropriately over a long period of time.

Embodiments of the present invention will be described below with reference to the drawings, but the present invention is not limited to the following embodiments.

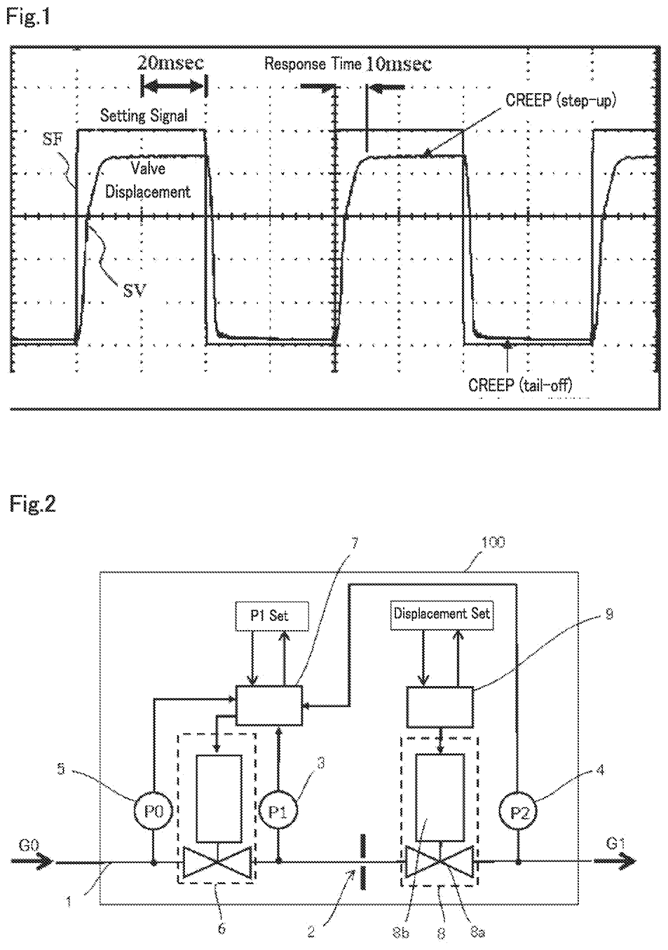

FIG. 2 shows a configuration of a flow rate control device 100 according to an embodiment of the present invention. The flow rate control device 100 includes a pressure control valve 6 provided on an inlet side of a flow path 1 for a gas G0, a flow rate control valve 8 provided downstream of the pressure control valve 6, a first (or an upstream) pressure sensor 3 for detecting a pressure P1 downstream of the pressure control valve 6 and upstream of the flow rate control valve 8, and a restriction part 2 provided downstream of the pressure control valve 6. The gas G0 supplied to the flow rate control device 100 may be a variety of gases used in the semiconductor manufacturing process, such as a material gas, an etching gas, or a carrier gas.

In the present embodiment, the restriction part 2 is constituted by an orifice plate provided upstream of the flow rate control valve 8. Since the area of the orifice is fixed, the orifice plate functions as a restriction part with a fixed opening degree. In another embodiment, the restriction part 2 may be provided downstream of the flow rate control valve 8, if it is placed in the vicinity of the flow rate control valve 8.

In the present specification, the “restriction part” is a portion where the cross-sectional area of the flow path is limited to smaller than that of the front and rear flow paths, and is configured by using an orifice plate, a critical nozzle, or a sonic nozzle, for example, but may also be configured by other elements. In this specification, the restriction part also includes a valve structure that is similar to a variable orifice having the distance between the valve seat and the valve element of the valve as the opening degree. Such a valve structure functions as a restriction part with a variable opening degree.

The flow rate control device 100 also includes a second (or downstream) pressure sensor 4 for measuring the downstream pressure P2 downstream of the flow rate control valve 8, and an inflow pressure sensor 5 for detecting the supply pressure P0 upstream of the pressure control valve 6. The supply pressure P0 is used to control a gas supply amount and a gas supply pressure from a gas supply device, such as a raw material vaporizer or a gas supply source, and the downstream pressure P2 is used for measuring a flow rate under a non-critical expansion condition, which will be described later. However, in other embodiments, the flow rate control device may not include the second pressure sensor 4 and the inflow pressure sensor 5.

The downstream side of the flow rate control valve 8 is connected to a process chamber of the semiconductor manufacturing equipment via a downstream valve (not shown). A vacuum pump is connected to the process chamber, and typically, a gas G1 whose flow rate is controlled by the flow rate control device 100 is supplied to the process chamber while the inside of the process chamber is evacuated. As the downstream valve, for example, a known Air Operated Valve whose opening and closing operation is controlled by compressed air may be used, or a solenoid valve may be used.

In the present embodiment, the flow rate control valve 8 is constituted by a piezo valve comprising a diaphragm valve element 8a provided so as to abut and isolate the valve seat and a piezo actuator including a piezoelectric element 8b for moving the valve element 8a. As the piezo actuator, the one obtained from NTK CERATEC, CO., LTD. may be utilized, for example. The piezo actuator may be constituted by a plurality of stacked piezoelectric elements accommodated in a cylindrical body or may be constituted by a single piezoelectric element accommodated in a cylindrical body. Similarly, a piezo valve is also suitably used as the pressure control valve 6.

The flow rate control device 100 includes a first control circuit 7 for controlling the opening and closing operation of the pressure control valve 6 based on an output of the first pressure sensor 3. The first control circuit 7 is configured to feedback control the pressure control valve 6 so that the difference between a set pressure received from outside and the upstream pressure P1 output from the first pressure sensor 3 becomes zero. Thus, it is possible to maintain the upstream pressure P1 downstream of the pressure control valve 6 to the set value.

Further, the flow rate control device 100 has a second control circuit 9 for controlling the flow rate control valve 8. In addition, although FIG. 2 shows an aspect in which the first control circuit 7 and the second control circuit 9 are provided separately, it is needless to say that they may be provided integrally.

The first control circuit 7 and the second control circuit 9 may be incorporated into the flow rate control device 100, or may be provided outside the flow rate control device 100. The first control circuit 7 and the secondary control circuit 9 are typically configured by CPU, memory M such as ROM, RAM, and A/D converters, and may also include computer programs configured to execute flow rate control operation that is to be described later. The first control circuit 7 and the second control circuit 9 can be realized by a combination of hardware and software.

Using the first control circuit 7 and the second control circuit 9, the flow rate control device 100 is configured to control the pressure control valve 6 so that the upstream pressure P1 output from the first pressure sensor 3 becomes the set value, and at the same time, to control the flow rate of the fluid flowing downstream of the flow rate control valve 8 by controlling the driving of the piezoelectric element 8b of the flow rate control valve 8.

In the flow rate control device 100, using the restriction part 2 with a fixed opening degree as the main element of the flow rate control, by controlling the upstream pressure P1 through the pressure control valve 6, it is possible to perform the flow rate control by pressure similar to the conventional pressure type flow rate control device. Furthermore, by controlling the opening degree of the flow rate control valve 8 while keeping the upstream pressure P1 constant using the pressure control valve 6, it is possible to control the gas flow rate with higher responsivity.

The flow rate control using the restriction part 2 with a fixed opening degree as the main element of the flow rate control is suitable for the control of a continuous flow in which the flow rate control is maintained at the set value for a relatively long period of time. On the other hand, the flow rate control such that the flow rate is determined by the opening degree of the flow rate control valve 8 at a flow rate less than the maximum set flow rate of the restriction part 2 with a fixed opening degree, i.e., the flow rate control such as using the flow rate control valve 8 as a variable orifice (restriction part with a variable opening degree) is suitable for the control of an intermittent flow.

Here, the control of the continuous flow broadly means the control of the fluid when the flow of the fluid continues, and may include cases such as, the state in which the fluid is flowing at 100% flow rate is changed to the state in which the fluid is flowing at 50% flow rate. In addition, when performing the control of the continuous flow using the restriction part 2 with a fixed opening degree, it is preferable to maintain the flow rate control valve 8 at a fully opening degree (the maximum opening degree) or, at least an opening degree that is larger than the opening degree of the restriction part 2 having a fixed opening degree.

On the other hand, the control of the intermittent flow is typically a pulsed flow rate control. However, it is not limited to the periodic opening and closing control at regular intervals, but also includes the pulsed opening and closing control performed at irregular intervals, as well as the opening and closing control such that the amplitude of the pulse fluctuates without being constant, and also includes the opening and closing control such that the pulse width varies.

The flow rate control device 100 can perform the flow rate control by utilizing the principle that, in the case where the control of the continuous flow is performed, when the critical expansion condition P1/P2≥about 2 (P1: upstream pressure, P2: downstream pressure, about 2 is in the case of argon gas) is satisfied, the flow rate of the gas passing through the restriction part 2 or the flow rate control valve 8 can be determined by the upstream pressure P1 regardless of the downstream pressure P2.

When the critical expansion condition is satisfied, the flow rate Q downstream of the flow rate control valve 8 is given by Q=K1·Av·P1 (K1 is a constant depending on the fluid species and fluid temperature, etc.). The flow rate Q is considered to be approximately proportional to the upstream pressure P1 and the valve opening degree Av of the flow rate control valve 8. In addition, if a second pressure sensor 4 is provided, it is possible to calculate the flow rate even when the above critical expansion condition is not satisfied with the difference between the upstream pressure P1 and the downstream pressure P2 being small. It is possible to calculate the flow rate Q based on the upstream pressure P1 and downstream pressure P2 measured by each pressure sensor, from a predetermined calculation formula Q=K2·Av·P2^{m}(P1−P2)ⁿ (where K2 is a constant depending on the fluid species and fluid temperature, in, n are indices derived from the actual flow rate). In addition, in a case such as when the flow rate control valve 8 is fully opened, under a condition in which the flow path cross-sectional area of the flow rate control valve 8 is larger than the flow path cross-sectional area of the restriction part 2, the flow rate can be calculated on the basis of Q=K1′·P1 or Q=K2′·P2^{m}(P1−P2)ⁿ by using fixed proportionality coefficients K1′ and K2′ in which the flow path cross-sectional area of the restriction part 2 is also considered. Then, it is possible to flow gas at an arbitrary set flow rate by feedback controlling the opening degree of the pressure control valve 6 so that the difference between the flow rate calculated from the pressure measurements and the set flow rate approaches 0.

On the other hand, when performing pulsed flow rate control, while keeping the upstream pressure P1 constant using the pressure control valve 6, the flow rate control device 100 performs pulsed opening and closing operation of the flow rate control valve 8. The flow rate of the gas supplied in a pulsed manner is determined by the magnitude of the upstream pressure P1, and the set opening degree at the time of opening the flow rate control valve 8. Even when the flow rate control valve 8 is open at the same opening degree, the larger the upstream pressure P1, the more the gas flows. Therefore, by arbitrarily setting the upstream pressure P1 and the set opening degree at the time of opening the flow rate control valve 8, it is possible to perform a pulsed gas supply over a wide flow rate control range.

Here, in the present embodiment, the control of the opening degree of the flow rate control valve 8 is not performed by feedback control by the displacement sensor as in the conventional art, but is performed by open-loop control of the flow rate control valve 8 based on an internal command signal defining the applied voltage to the piezoelectric element 8b that is generated from the input set flow signal. Hereinafter, a concrete description will be given.

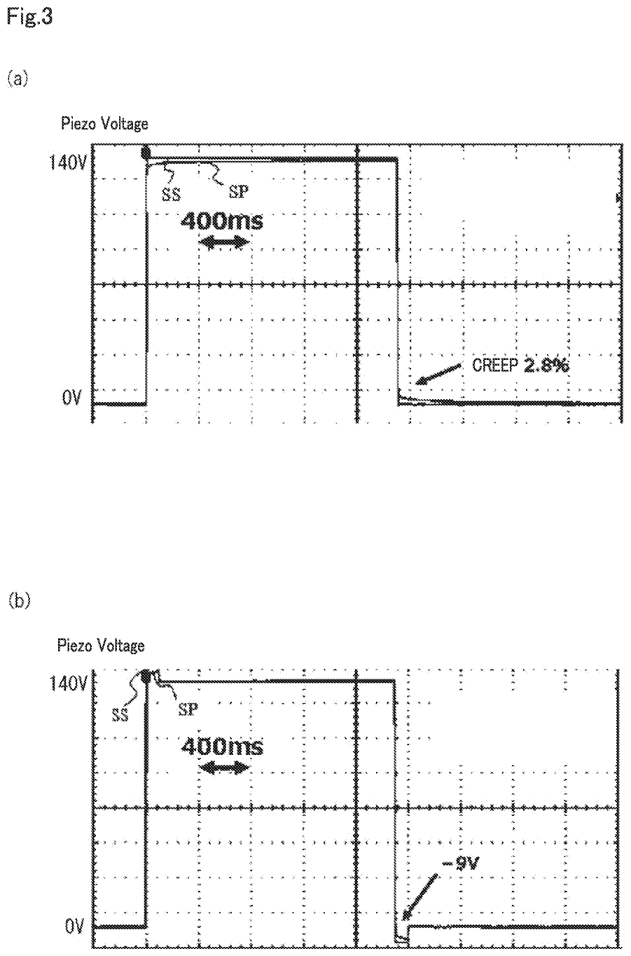

FIGS. 3(a) and (b) are graphs showing the relationship between the piezo voltage setting signal SS to the flow rate control valve (piezo valve) 8 and the piezo displacement (strain output) SP measured by using a displacement sensor (specifically strain gauge fixed to the piezoelectric element). FIG. 3(a) shows the case of inputting the setting signal without correction, FIG. 3(b) shows the case of inputting the signals that are corrected to apply excessive voltages in the primary periods at the rise time and at the fall time of the piezo voltage.

In FIGS. 3(a) and 3(b), signals of a relatively long period of time (the on period is about 2 seconds) are shown. The setting signal SS is designed to be updated, for example, every 100 msec. In FIG. 3(b), under this constraint, the signal is corrected to a set voltage of 149 V in which 9 V is added in a period of 100 msec immediately after the rise of the flow rate, a set voltage of 140 V in a subsequent period, a set voltage of −9 V in which −9 V is added in a period of 100 msec immediately after the fall of the flow rate, and a set voltage of 0 V in a subsequent period.

As can be seen by comparing FIG. 3(a) and FIG. 3(b), in a predetermined period of the initial rise and the initial fall (i.e., immediately after transient), by adding a predetermined excessive voltage, a change in the piezo displacement SP is observed and the suppression of the creep phenomenon can be confirmed. Therefore, even if the feedback control using the displacement sensor is not performed, the creep phenomenon can be suppressed by the signal correction, and the desired opening degree adjustment can be performed.

However, when inputting a corrected setting signal to the control circuit of the piezoelectric element as described above, a constraint may be imposed on the setting. Therefore, it is conceivable to generate an internal command signal corresponding to the input setting signal and to drive the piezo valve based on the signal.

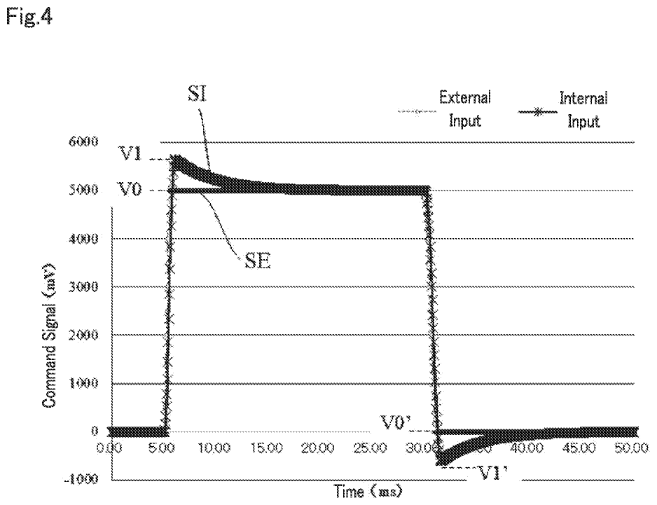

FIG. 4 is a graph showing an example of an internal command signal SI generated from an external input signal SE of the piezo voltage based on the setting signal. In this example, the signal processing using the derivative action has been made, thereby, the voltage V1 exceeding the target voltage V0 (i.e., voltage corresponding to the target piezo displacement) at the time of rising (here a voltage V1 that is larger than the target voltage V0) is once applied, then, the internal command signal SI is generated so that a voltage approaching the target voltage V0 is applied. Similarly, at the time of falling, the voltage V1′ exceeding the target voltage V0′ (here, the voltage V1′ is smaller than the target voltage V0′) is once applied, then the internal command signal is generated so that a voltage approaching the target voltage V0′ is applied.

In the signal processing using derivative or differential action, the maximum value and the time change of the excessive voltage applied immediately after the transient period are varied depending on the constant of the height component and the constant of the time component. Therefore, it is possible to arbitrarily create the signal waveform of the internal command signal SI (or piezo-driven voltage) by appropriately setting these constants included in the control function. Therefore, if the control function is determined by selecting an appropriate constant at first so as to fit the creep phenomenon that occurs in the piezo valve to be controlled, it is possible to appropriately suppress the creep phenomenon even with the open-loop control thereafter. In addition, by using derivative action, the driving of the piezo valve at steep acceleration is suppressed, and a smoother valve drive can be performed. Therefore, the risk of the failure occurrence can be reduced even when repeating the opening and closing operations many times at high frequencies.

In the signal shown in FIG. 4, the period is about 50 msec, and the signal frequency is about 20 Hz. Even in such a signal having a relatively high frequency, the internal command signal effective in suppressing the creep phenomenon can be easily generated. The driving method of the piezo valve in the present embodiment is suitably applied to perform pulsed flow rate control, when a continuous cycle signal of, for example, 1 to 100 Hz, especially 5 to 50 Hz is given as the setting signal. According to such a method, pulsed gas supply can be performed at the desired gas flow rate and gas volume w % bile suppressing the creep phenomenon.

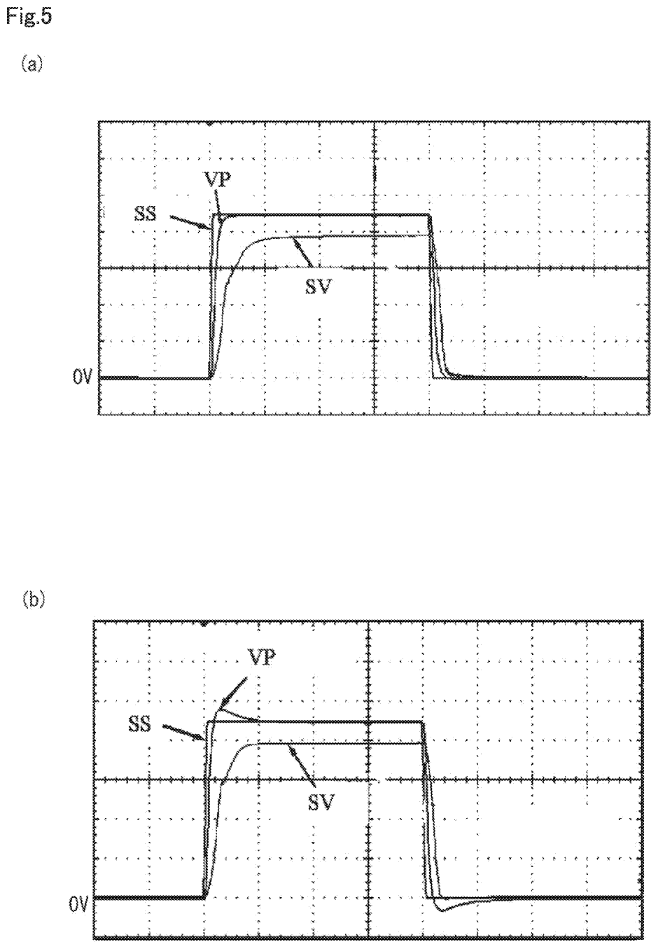

FIG. 5(a) is a graph showing the valve displacement when the valve is driven based on the setting signal without generating the internal command signal subjected to a correction process as shown in FIG. 4. FIG. 5(b) is a graph showing the valve displacement when the valve is driven using a generated internal command signal subjected to a correction process.

As can be seen by comparing FIG. 5(a) and FIG. 5(b), even when the same setting signal SS is given, when using the corrected internal command signal, the driving voltage controlled so as to once exceed the target voltage and then approach the target voltage is applied as the piezo driving voltage VP. By controlling the driving voltage in such a manner, the valve displacement signal SV becomes horizontal, i.e., the creep phenomenon is suppressed, in both on period and off period, and the proper opening degree of the piezo valve is maintained. Therefore, without performing feedback control using the displacement sensor, an appropriate pulsed gas supply can be performed by open-loop control of the driving voltage.

Although the aspect of performing signal correction using the derivative operation has been described above, as long as it is possible to apply excessive voltages at the time of rising and falling, the internal processing signal for suppressing the creep phenomenon by various signal correction processes may be generated. The control function used in the signal correction process may be appropriately changed in accordance with the magnitude of the target flow rate or the target driving voltage. If the degree of the creep phenomenon varies depending on the magnitude of the target flow rate, it is preferable to generate a suitable internal processing signal. For this reason, a table showing the relationship between the target flow rate and the parameter of the internal processing signal may be stored in a memory, at the time of flow rate control, the internal processing signal may be generated according to the appropriate parameter read. Thereby, the creep phenomenon at each flow rate may be more effectively suppressed.

While embodiments of the present invention have been described above, various modifications are possible. For example, different from the flow rate control device 100 as shown in FIG. 2, a restriction portion 2 with a fixed opening degree may be provided downstream of the flow rate control valve 8. In addition, a third pressure sensor may be further provided between the restriction part 2 with a fixed opening degree and the flow rate control valve 8, and the flow rate control based on an output of the third pressure sensor may be performed when performing control of a continuous flow.

In addition, in the flow rate control device according to the embodiment of the present invention, the flow rate control valve is not limited to a normally closed type but may also be a normally open type piezo valve, even in this case, by controlling the driving voltage applied to the flow rate control valve based on the internal command signal including the excessive voltage of the transient period, it is possible to perform the flow rate control with good accuracy and responsivity. Furthermore, when using an orifice plate as the restriction part 2 with a fixed opening degree, the above flow rate control valve 8 and the orifice plate may be integrally provided in the form of a known orifice built-in valve. When provided as an orifice built-in valve, the orifice plate and the valve seat are provided in a hole for mounting the flow rate control valve 8, and the valve main body (such as a valve element or an actuator) of the flow rate control valve 8 is fixed on top of it. In this way, the volume between the orifice plate and the valve element of the flow rate control valve 8 can be reduced by placing them close to each other, and the responsivity of the flow rate control can be improved.

Moreover, by using the flow rate control valve 8 shown in FIG. 2 independently without combining the upstream pressure control valve 6 and the restriction part 2, a high-speed servo-type flow rate control device may be constituted.

### INDUSTRIAL APPLICABILITY

The flow rate control device and the flow rate control method according to the embodiments of the present invention are used, for example, in semiconductor manufacturing equipment, chemical plants, etc., and are suitably used in an application in which the pulsed flow rate control is required such as an ALD process.

### REFERENCE SIGNS LIST

1 Flow path
2 Restriction part
3 First pressure sensor
4 Second pressure sensor
5 Inflow pressure sensor
6 Pressure control valve
7 First control circuit
8 Flow rate control valve
8a Valve element
8b Piezoelectric element (piezo actuator)
9 Second control circuit
100 Flow rate control device

1. A flow rate control device comprising:
a flow rate control valve having a valve element and a piezoelectric element for moving the valve element; and
a control circuit for controlling the operation of the flow rate control valve,
wherein, in order to perform a pulsed fluid supply, the control circuit is configured to open-loop control a voltage applied to the piezoelectric element so that a voltage exceeding a target voltage corresponding to a target displacement of the piezoelectric element is once applied and then a voltage approaching the target voltage is applied, when a pulsed flow rate setting signal is given.

2. The flow rate control device according to claim 1, wherein the control circuit is configured to change a control function of the voltage applied to the piezoelectric element depending on a target flow rate indicated by the pulsed flow rate setting signal.

3. The flow rate control device according to claim 1, wherein the pulsed flow rate setting signal is a continuous periodic signal having a frequency of 1 Hz or more and 100 Hz or less.

4. The flow rate control device according to claim 1, further comprising:
a pressure control valve provided upstream of the flow rate control valve;
a pressure sensor for measuring a pressure downstream of the pressure control valve and upstream of the flow rate control valve; and
a restriction part with a fixed opening degree,
wherein when performing control of a continuous flow, a flow rate control is performed by using the restriction part with a fixed opening degree and based on an output of the pressure sensor, and when performing control of a pulsed flow, a flow rate control is performed by using the flow rate control valve as a restriction part with changeable opening degrees.

5. A flow rate control method performed in a flow rate control device comprising a flow rate control valve having a valve element and a piezoelectric element for moving the valve element, the flow rate control method including:
a step of receiving a pulsed flow rate setting signal for performing a pulsed fluid supply;
a step of generating an internal command signal for determining a voltage applied to the piezoelectric element based on the flow rate setting signal, when receiving the pulsed flow rate setting signal; and
a step of applying a voltage to the piezoelectric element based on the generated internal command signal,
wherein the internal command signal is generated as a signal approaching a target voltage after once applying a voltage exceeding the target voltage corresponding to a target displacement of the piezoelectric element, and
the voltage applied to the piezoelectric element is open-loop controlled.
